(19) United States
(12) Patent Application Publication
(10) Pub. No.: US 2018/0229333 A1
(43) Pub. Date: Aug. 16, 2018

(54) SOLDER PASTE AND MOUNT STRUCTURE OBTAINED BY USING SAME

(71) Applicant: Panasonic Intellectual Property Management Co., Ltd., Osaka (JP)

(72) Inventors: HIROHISA HINO, Osaka (JP); NAOMICHI OHASHI, Hyogo (JP); YASUHIRO SUZUKI, Osaka (JP)

(21) Appl. No.: 15/872,954

(22) Filed: Jan. 16, 2018

(30) Foreign Application Priority Data
Feb. 10, 2017 (JP) 2017-023468
Oct. 31, 2017 (JP) 2017-210605

(51) Int. Cl. B23K 35/02; H05K 3/34; B23K 35/26; C08L 63/10; B23K 35/362; B23K 101/42

(52) U.S. Cl. CPC B23K 35/025; H05K 3/3484; H05K 3/3463; B23K 2201/42; C08L 63/10; B23K 35/362; B23K 35/264

(57) ABSTRACT

Provided herein are a solder paste and a mount structure having excellent repairability while maintaining high adhesion at the operating temperature of a semiconductor component. The solder paste is configured from a solder powder and a flux. The flux contains an epoxy resin, a curing agent, a rubber modified epoxy resin, and an organic acid. The rubber modified epoxy resin is contained in a proportion of 3 weight % to 35 weight % with respect to the total weight of the flux.

### TECHNICAL FIELD

The technical field relates mainly to solder pastes used for soldering of semiconductor components, electronic components, and the like to a circuit board, particularly a solder paste that contains epoxy resin as its flux component, and to a mount structure obtained by using such a solder paste.

### BACKGROUND

Mobile devices such as cell phones and PDAs (Personal Digital Assistants) have never been smaller and more functional. A variety of mount structures such as BGA (Ball Grid Array), and CSP (Chip Scale/Size Package) are available as a mount technology for accommodating such advancements. Mobile devices are prone to mechanical loads such as a dropping impact. A QFP (Quad Flat Package) is used to absorb impact at its lead portion. BGA and CSP however do not have leads that relieve impact. It is also important to provide reliability against impact in these structures as well.

A common Sn—Pb eutectic solder has a melting point of 183° C. In contrast, a Ag—Sn—Cu-based solder, a typical example of modern lead-free solders, has a melting point about 30° C. higher than the melting point of the Sn—Pb eutectic solder, and the profile temperature of a reflow furnace reaches a temperature as high as 220 to 260° C. For mounting of components having weak high-temperature resistance to a circuit board, such components are separately bonded in a separate step by spot soldering. This has posed a serious drawback in productivity.

This has led to the use of low-melting-point Pb-free solders, for example, Sn—Zn—, Sn—Ag—In—, and Sn—Bi-based solders, which have lower melting points than that of the Sn—Ag—Cu-based solder (hereinafter, referred to as “SAC solder”). However, a BGA connection using Sn—Zn—, Sn—Ag—In—, and Sn—Bi-based solders has not been fully established with regard to the connection reliability of the solder joint, particularly reliability against impact.

This issue is addressed in related art. For example, Japanese Patent Nos. 5373464 and 5357784 propose semiconductor mount structures using a resin flux solder paste (hereinafter, also referred to simply as “solder paste”) that contains a thermosetting resin in the flux to improve reliability against impact at a joint, and methods for producing such a semiconductor mount structure. In the solder paste of related art such as above, the resin and the solder separate from each other in a process that applies heat to melt bond the solder, and the resin covers the periphery of the solder, and forms a reinforcing structure. As a result of this reinforcement, a solder joint can have improved strength, and reliability against impact can improve. In actual practice, such mounting involves printing a solder paste at a predetermined location such as a wire electrode of a circuit board using a metal mask or the like, and heating with a reflow furnace. Here, the resin flux acts to initiate a reduction reaction that chemically removes the oxide films from the metal surface and the solder powder surface to be soldered. Specifically, the resin flux develops a fluxing effect, and melt bonds the joint portion. Because the epoxy resin continues to cure, the bonding of the wire electrode of the circuit board to a component, and the resin reinforcement can be completed in a single reflow step.

Desirably, the solder paste allows for repair, meaning that the mounted semiconductor component can be removed after being tested. That is, in case of defects such as a connection failure occurring in the mounting of the expensive semiconductor component, it is important for cost reduction to remove only the detective semiconductor component, and remount a new semiconductor component, instead of discarding the semiconductor component altogether with the substrate. However, the solder pastes described in the foregoing patents use a thermosetting resin for the solder-covering, reinforcing epoxy resin, and, unlike a solder, are probably not removable by being melted under heat. The joint formed by the solder pastes described in the foregoing patents slightly softens when heated to a temperature equal to or greater than the glass transition point Tg, and can probably be removed by applying a strong mechanical force under a temperature equal to or greater than Tg. However, this would take a very long time. Many traditional solder pastes also use a common bisphenol-based epoxy, and remain strongly bonded even at a temperature equal to or greater than Tg. This often results in the solder paste being detached with the solder resist of the circuit board under the force applied to remove the solder paste. Indeed, it is very difficult to remount (repair) a semiconductor device.

### SUMMARY

The present disclosure is intended to provide a solution to the foregoing problems of related art, and it is an object of the present disclosure to provide a solder paste and a mount structure having desirable high-temperature repairability while remaining highly adherent at room temperature where a semiconductor component operates.

A solder paste of an aspect of the present disclosure is configured from a solder powder and a flux. The flux contains an epoxy resin, a curing agent, a rubber modified epoxy resin, and an organic acid. The rubber modified epoxy resin is contained in a proportion of 3 weight % to 35 weight % with respect to the total weight of the flux.

A mount structure of an aspect of the present disclosure is a mount structure including an electronic component mounted with the solder paste, and includes a conductive portion where the electronic component and the circuit board are metallically bonded to each other, and a reinforcing portion formed by a cured product of the flux covering the periphery of the conductive portion.

With the solder paste of the aspect of the present disclosure, a joint can be formed that is easily removable under high temperature while remaining highly adherent at room temperature, where a semiconductor component operates.

### BRIEF DESCRIPTION OF THE DRAWINGS

FIG. 1 is across sectional view of a ball portion of a CSP bonded with a solder paste of an embodiment of the present disclosure.

FIG. 2A is a cross sectional explanatory diagram schematically representing a process for bonding a ball portion of a CSP with the solder paste of the embodiment of the present disclosure.

FIG. 2B is a cross sectional explanatory diagram schematically representing a process for bonding a ball portion of a CSP with the solder paste of the embodiment of the present disclosure.

FIG. 2C is a cross sectional explanatory diagram schematically representing a process for bonding a ball portion of a CSP with the solder paste of the embodiment of the present disclosure.

FIG. 3A is a cross sectional explanatory diagram schematically representing a process for bonding a chip component with the solder paste of the embodiment of the present disclosure.

FIG. 3B is a cross sectional explanatory diagram schematically representing a process for bonding a chip component with the solder paste of the embodiment of the present disclosure.

FIG. 3C is a cross sectional explanatory diagram schematically representing a process for bonding a chip component with the solder paste of the embodiment of the present disclosure.

FIG. 4 is across sectional schematic view representing a method for measuring the shear strength of a chip component.

### DESCRIPTION OF EMBODIMENTS

An embodiment of the present disclosure is described below with reference to the accompanying drawings.

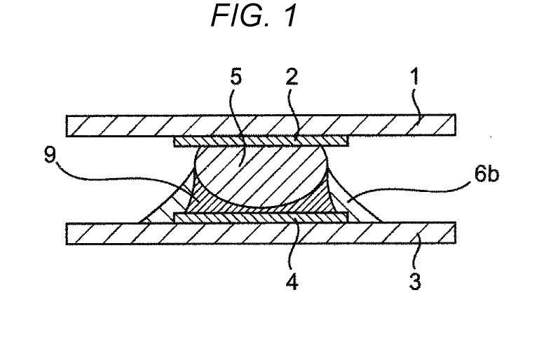

A solder paste of an embodiment of the present disclosure contains a solder powder and a flux, and may contain other components, as needed. FIG. 1 is a cross sectional view of a CSP bonded with the solder paste of the embodiment of the present disclosure. The solder bonding a circuit board 1 and a circuit board 3 to each other contains a solder powder and a flux, and a joint is obtained that includes a conductive portion 9 derived from the solder powder component and metallically bonding the solder bump 5 to the circuit board 3, and a reinforcing portion 6b formed by a cured product of the flux covering the periphery of the conductive portion. By the presence of the flux-derived reinforcing portion 6b surrounding the conductive portion 9 forming the metallic bond, the reliability against impact can improve.

The flux contained in the solder paste of the embodiment of the present disclosure contains an epoxy resin, a curing agent, a rubber modified epoxy resin, and an organic acid, and may contain other components, as needed. The rubber modified epoxy resin contained in the flux of the solder paste of the embodiment of the present disclosure adds tenacity to the solder paste. Upon curing, the rubber modified epoxy resin becomes crosslinked, and forms a jungle gym structure. In this structure, the rubber modified epoxy resin tends to undergo spring-like molecular vibration, and show low elastic modulus at elevated temperatures. The solder joint formed by the solder paste of the embodiment of the present disclosure can thus be removed under only a small external force at high temperature, and provides desirable repairability. The rubber modified epoxy resin is used in a proportion of 3 weight % to 35 weight % with respect to the total weight of the flux. With the rubber modified epoxy resin used in this content range, a joint can be formed that has excellent repairability at high temperature.

When the rubber modified epoxy resin is an epoxy resin having a butadiene skeleton, the high-temperature adhesion of the solder paste can be reduced more than when the rubber modified epoxy resin does not contain an epoxy resin having a butadiene skeleton. This makes it easier to remove the solder paste, and the repair process becomes easier. The epoxy resin having a butadiene skeleton may be contained in any proportion relative to the other components. However, the epoxy resin having a butadiene skeleton is preferably used in a proportion of 2 weight % to 30 weight % with respect to the total weight of the flux. With the epoxy resin having a butadiene skeleton in this content range, the high-temperature adhesion of the solder paste is more effectively reduced.

When the rubber modified epoxy resin is an epoxy resin having a urethane skeleton, the high-temperature adhesion of the solder paste can be reduced more than when the rubber modified epoxy resin does not contain an epoxy resin having a urethane skeleton. This makes it possible to improve the connection reliability of the semiconductor component. The epoxy resin having a urethane skeleton may be contained in any proportion relative to the other components. However, the epoxy resin having a urethane skeleton is preferably in a proportion of 1 weight % to 20 weight % with respect to the total weight of the flux. With the epoxy resin having a urethane skeleton in this content range, the room-temperature adhesion of the solder paste is improved.

The rubber modified epoxy resin may be a combination of an epoxy resin having a butadiene skeleton, and an epoxy resin having a urethane skeleton. In this case, the solder paste can have both high adhesion at room temperature, and low adhesion at high temperature. The epoxy resin having a butadiene skeleton may be contained in any proportion relative to the other components. However, the epoxy resin having a butadiene skeleton is preferably in a proportion of 2 weight % to 20 weight % with respect to the total weight of the flux. The epoxy resin having a urethane skeleton may be contained in any proportion relative to the other components. However, the epoxy resin having a urethane skeleton is preferably in a proportion of 1 weight % to 15 weight % with respect to the total weight of the flux. With the rubber modified epoxy resin in these content ranges, high room-temperature adhesion, and desirable high-temperature repairability can be effectively achieved.

The solder powder contained in the solder paste of the embodiment of the present disclosure is a solder powder containing tin, and may be a solder powder containing 22 weight % to 68 weight % of Bi, 0 weight % to 2 weight % of Ag, 0 weight % to 73 weight % of In, and the balance tin. Specifically, the solder powder may be, for example, 42Sn-58Bi, 42Sn-57Bi-1.0Ag, or 16Sn-56Bi-28In. However, the solder powder is not limited to these. With the contents of the solder powder components falling in these ranges, the solder powder used for the solder paste of the embodiment of the present disclosure can have a melting point of less than 200° C.

Examples of the other components of the flux contained in the solder paste of the embodiment of the present disclosure include common modifying agents, and common additives. A low-boiling-point solvent or diluent may be added to reduce the viscosity of the solder paste, and impart fluidity. It is also effective to add a thixotropy imparting agent, such as hydrogenated castor oil and stearamide, for the purpose of retaining the print shape.

The following specifically describes the components of the solder paste of the embodiment of the present disclosure.

### Solder Powder

In the solder paste of the embodiment of the present disclosure, the solder powder used is preferably one having a melting point of 200° C. or less. The lower limit of the melting point of the solder particle is not particularly limited, and is preferably 130° C. or more. When the solder powder has a melting point of 200° C. or less, the melting point of the solder powder used for the solder paste is lower than the melting point (220° C.) of the tin-silver-copper (SAC) solder powder used for solder balls of BGA and CSP semiconductors, and remelting of the SAC solder powder does not occur. The composition of the solder powder is not particularly limited, and may be, for example, a Sn-based alloy containing 22 weight % to 68 weight % of Bi, 0 weight % to 2 weight % of Ag, 0 weight % to 73 weight % of In, and the balance Sn. Specifically, preferred for use are SnBi-based alloys such as 42Sn-58Bi, 42Sn-57Bi-1.0Ag, and 16Sn-56Bi-28In. The content of the solder powder with respect to the total mass of the solder paste of the embodiment of the present disclosure ranges from 40 weight % to 95 weight %, more preferably 78 weight % to 85 weight %. With the solder powder content falling in these ranges in the solder paste of the embodiment of the present disclosure, the connection reliability of the joint, and the printability of the paste can be effectively improved.

In this specification, the composition of the solder powder is represented by connecting the symbols of the solder powder elements with hyphens. In this specification, the numerical values or numerical ranges attached immediately in front of the metallic elements describe the metal composition of the solder powder, and indicate the amount of each element in the metal composition in mass % (=weight %), as commonly practiced in the art. The solder powder may contain trace amounts of other metals, for example, such as Ni, Zn, Sb, and Cu, provided that the solder powder is configured essentially from the elements listed.

In this specification, the melting point of the solder powder refers to the temperature of the solder powder as melted when the state changes of a heated sample is observed in a heating process, and may be measured using, for example, DSC, and TG-DTA.

### Flux

The flux in the embodiment of the present disclosure contains an epoxy resin, a rubber modified epoxy resin, a curing agent, and an organic acid (activating agent). In addition to the epoxy resin and the curing agent contained as resin components, the flux of the embodiment of the present disclosure may contain a curing promoting agent, as needed. The flux content with respect to the total mass of the solder paste of the embodiment of the present disclosure ranges from 5 weight % to 60 weight %, more preferably 15 weight % to 22 weight %. With the flux content falling in these ranges in the solder paste of the embodiment of the present disclosure, the connection reliability of the joint, and the printability of the paste can effectively improve. The following more specifically describes the components of the resin flux.

### Epoxy Resin

The epoxy resin typically refers to a thermosetting resin that has an epoxy group within its structure, and that can be cured by heat. The embodiment of the present disclosure uses an epoxy resin that is liquid at ordinary temperature. By using an epoxy resin that is liquid at ordinary temperature, other components, including the solder powder, can be dispersed with ease. As used herein, “liquid at ordinary temperature” means that there is fluidity in a temperature range of 5° C. to 28° C., particularly at room temperature of about 20° C. under the atmospheric pressure. The epoxy resin that is liquid at ordinary temperature is not particularly limited in terms of a molecular weight and a molecular structure, provided that the epoxy resin has two or more epoxy groups within the molecule. Examples of such epoxy resins include various liquid epoxy resins, including glycidyl ether, glycidyl amine, glycidyl ester, and olefin oxidized (alicyclic) liquid epoxy resins. Specific examples include bisphenol epoxy resins, such as bisphenol A epoxy resins, and bisphenol F epoxy resins; hydrogenated bisphenol epoxy resins, such as hydrogenated bisphenol A epoxy resins, and hydrogenated bisphenol F epoxy resins; biphenyl epoxy resins, naphthalene ring-containing epoxy resins, alicyclic epoxy resins, dicyclopentadiene epoxy resins, phenol novolac epoxy resins, cresol novolac epoxy resins, triphenylmethane epoxy resins, aliphatic epoxy resins, and triglycidyl isocyanurate. These may be used either alone or in a combination of two or more. In terms of reducing the viscosity of a liquid epoxy resin composition used for sealing semiconductors, and improving the quality of the cured product, preferred as the epoxy resin that is liquid at ordinary temperature are bisphenol epoxy resins, and hydrogenated bisphenol epoxy resins. An epoxy resin that is solid at ordinary temperature may be used in combination. Examples of such epoxy resins that are solid at ordinary temperature include biphenyl epoxy resins, dicyclopentadiene epoxy resins, and triazine skeleton epoxy resins. The epoxy resin is used in a range of preferably 50 mass % to 90 mass %, particularly 66 mass % to 82 mass % with respect to the total mass of the flux. With the epoxy resin content falling in these ranges in the flux of the embodiment of the present disclosure, the connection reliability of the joint can effectively improve.

For advantages such as strong adhesion and insulation, epoxy resins are used in a range of applications including adhesives, coating materials, and electrical and electronic materials. The inherent drawback, however, is a lack of toughness. Because of rigidity, cracking and other defects tend to occur under a mechanical load. Specifically, the component becomes detached when a mechanical load is applied to its joint portion, and the reliable lifetime becomes shorter. The epoxy resin can be rendered tenacious by, for example, polymer alloying of a flexible resin (forming an interpenetrating polymer network, or IPN, by adding a strong thermoplastic polymer, and thus forming an admixture of different forms), or by forming a sea-island structure, or introducing various rubber skeletons. Possible examples of such methods include forming a polymer alloy of epoxy resin and acrylic resin, and forming a sea-island structure of epoxy resin and silicone resin. These techniques involve providing a special, low-elastic characteristic by creating a localized micro state for different resins. However, stably creating such a dispersive state is highly difficult. In light of this, the solder paste of the embodiment of the present disclosure contains a rubber modified epoxy resin containing in its structure an epoxy resin as a functional group that provides crosslinkability, and a functional group that provides tenacity to the solder paste.

### Rubber Modified Epoxy Resin

The rubber modified epoxy resin used in the embodiment of the present disclosure is an epoxy resin of a structure having an epoxy group, and a functional group that renders the solder paste tenacious. The functional group that renders the solder paste tenacious refers to a functional group having excellent elasticity against mechanical stimulation and thermal stimulation, and that can make the cured product of the solder paste tenacious to impart high ductility to the epoxy resin. The functional group that makes the cured product of the solder paste tenacious has a structure that can improve elasticity. Examples of such a structure include a structure that is bent in a certain angle. Non-limiting examples of the functional group include a butadiene group, a urethane group, an alkylene ether group, and a fatty acid group. With the foregoing structure, the rubber modified epoxy resin of the embodiment of the present disclosure shows spring-like elasticity at room temperature, but the elasticity decreases at elevated temperature, particularly, at a temperature equal to or greater than Tg, because of the very high molecular mobility at such high temperatures. With the solder paste of the embodiment of the present disclosure containing a rubber modified epoxy resin having the structure described above, the joint formed by the solder paste can be removed with only a small external force, and can have desirable repairability at high temperature.

The rubber modified epoxy resin having a butadiene skeleton within the molecule has both the butadiene structure and an epoxy group within the molecule, and has both strong adhesion and strong tenacity. Two of the possible forms of the rubber modified epoxy resin having a butadiene skeleton within the molecule are one in which a butadiene skeleton occurs in the main chain (including 1,4-polybutadiene), and one in which a butadiene skeleton occurs in a side chain (including 1,2-polybutadiene). Either form can develop the rubber characteristics, and can preferably be used. Polybutadiene, which is hydrogenated at the double bonds, also have similar rubber characteristics, and shows excellent heat resistance because the lack of double bonds makes the molecule hardly oxidizable. The rubber modified epoxy resin having a butadiene skeleton within the molecule is used as a flux component, and is preferably liquid. The rubber modified epoxy resin having a butadiene skeleton within the molecule may be one that liquefies when used with a liquid epoxy resin, or one that liquefies by addition of a solvent. When the rubber modified epoxy resin having a butadiene skeleton within the molecule is incorporated in a cross-linked structure by reacting with a curing agent, the butadiene skeleton, which has a relatively hard structure at room temperature, shows rubber-like elasticity in a high-temperature environment (specifically, for example, 160° C.) because of the strong molecular motion at such a high temperature. A cured product of the rubber modified epoxy resin having a butadiene skeleton within the molecule therefore has very low elasticity. Thus, when used as the rubber modified epoxy resin, the rubber modified epoxy resin having a butadiene skeleton within the molecule can provide a solder paste that strongly adheres to the base material at room temperature, and that has weak adhesion in a high-temperature environment. The solder paste can be removed with ease by physically applying a force using a spurtle or the like in a high-temperature environment. An example of the rubber modified epoxy resin having a butadiene skeleton within the molecule is represented by the chemical formula 1 below. However, the structure is not limited to the structure represented by chemical formula 1, and any epoxy resin may be used that has a butadiene skeleton and an epoxy group within the molecule. Specific examples include commercially available products such as Epolead PB3600, PB4700 (both are available from Diecel Corporation), Nisseki Polybutadiene E-1000-3.5 (Nippon Petrochemicals), and R-15EPT, R-45EPT (Nagase ChemteX Corporation).

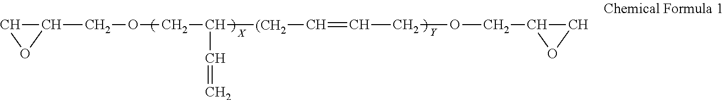

(X and Y represent the number of units.)

The rubber modified epoxy resin having a urethane skeleton within the molecule has both the urethane structure and an epoxy group within the molecule, and has both strong adhesion and strong tenacity. An example of the rubber modified epoxy resin having a urethane skeleton within the molecule is represented by the chemical formula 2 below. However, the structure is not limited to the structure represented by chemical formula 2, and any epoxy resin may be used that has a urethane skeleton and an epoxy group within the molecule. The urethane skeleton is formed typically by the reaction between polyol and polyisocyanate, and an epoxy group is introduced later. However, the method of production is not particularly limited. The rubber modified epoxy resin having a urethane skeleton within the molecule may have various structures (e.g., aliphatic skeleton) on the other main chain skeletons, provided that a urethane skeleton and an epoxy group are present. The rubber modified epoxy resin having a urethane skeleton within the molecule is used as a flux component, and is preferably liquid. The rubber modified epoxy resin having a urethane skeleton within the molecule may be one that liquefies when used with a liquid epoxy resin, or one that liquefies by addition of a solvent. When the rubber modified epoxy resin having a urethane skeleton within the molecule is incorporated in a cross-linked structure by reacting with a curing agent, the urethane skeleton, with its hard structure, shows high shear adhesion under room temperature. Thus, when used as the rubber modified epoxy resin, the rubber modified epoxy resin having a urethane skeleton within the molecule can provide a solder paste that, with the tenacity of the urethane skeleton, does not easily crack even when a shear force is applied to the chip and other components at room temperature, and that does not easily detach itself. A cured product of the rubber modified epoxy resin having a urethane skeleton can thus exhibit high release reliability against shear. Specific examples of the rubber modified epoxy resin having a urethane skeleton within the molecule include commercially available materials such as EPU-7N, and EPU-73B (ADEKA).

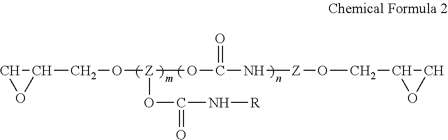

(R represents alkyl, Z represents an aliphatic skeleton, and m and n represent the number of units.)

Preferably, the proportion of the rubber modified epoxy resin in the solder paste is 3 weight % to 35 weight % with respect to the total flux weight. With the rubber modified epoxy resin contained in the solder paste in such a proportion with respect to the total flux weight, the connection reliability and the high-temperature repairability of the components at the joint can effectively improve.

In a high-temperature range equal to or greater than the Tg of the resin flux, the adhesion strength of when a chip component is mounted and attached to a circuit board with a solder paste using the rubber modified epoxy resin having a butadiene skeleton is significantly weaker than when a solder paste that does not contain the rubber modified epoxy resin is used. That is, a joint formed with the solder paste using the rubber modified epoxy resin having a butadiene skeleton can be removed with ease at high temperature. Other desirable properties, including desirable printability, can be obtained when the epoxy resin having a butadiene skeleton is used as the rubber modified epoxy resin of the solder paste, and contained in a proportion of 2 weight % to 30 weight % of the total flux weight.

At room temperature, the adhesion strength of when a chip component is mounted and attached to a circuit board with the solder paste using the rubber modified epoxy resin having a urethane skeleton as in the embodiment of the present disclosure is higher than when a solder paste that does not contain the rubber modified epoxy resin is used. Other desirable properties, including desirable printability, can be obtained when the epoxy resin having a urethane skeleton is used as the rubber modified epoxy resin of the solder paste, and contained in a proportion of 1 weight to 20 weight of the total flux weight. In a high-temperature range equal to or greater than the Tg of the resin flux, the adhesion strength of when a chip component is mounted and attached to a circuit board using the solder paste using the rubber modified epoxy resin having a urethane skeleton is significantly weaker than when a solder paste that does not contain the rubber modified epoxy resin is used. That is, the solder paste using the rubber modified epoxy resin having a butadiene skeleton can be removed with ease at high temperature.

The rubber modified epoxy resin having a butadiene skeleton, and the rubber modified epoxy resin having a urethane skeleton may be used together. For a solder paste containing 2 weight to 20 weight of the butadiene skeleton-containing epoxy resin with respect to the total flux weight, and 1 weight to 15 weight of the urethane skeleton-containing epoxy resin with respect to the total flux weight, the adhesion strength of when a chip component is mounted and attached to a circuit board using the solder paste was found to be weaker than when the solder paste does not contain the rubber modified epoxy resin in a high-temperature range equal to or greater than the Tg of the resin flux. At room temperature, the adhesion strength was found to be higher than when the solder paste does not contain the rubber modified epoxy resin. That is, both the high-adhesion characteristic at room temperature, and the low-adhesion characteristic at high temperature can be obtained by adjusting the contents of the two rubber modified epoxy resins.

### Curing Agent

The curing agent may be a common epoxy resin curing agent, for example, such as acid anhydrides, phenol novolac, various thiol compounds, various amines, dicyandiamide, imidazoles, metal complexes, and adduct compounds thereof, for example, such as an adduct modified product of polyamine. However, the curing agent is not limited to these. Particularly preferred for use are imidazoles, which satisfy both single-component properties and solder meltability. Non-limiting examples of imidazoles include 2MZ, C11Z, 2PZ, 2E4MZ, 2P4MZ, 1B2MZ, 1B2PZ, 2MZ-CN, 2E4MZ-CN, 2PZ-CN, C11Z-CN, 2PZ-CNS, C11Z-CNS, 2MZ-A, C11Z-A, 2E4MZ-A, 2P4MHZ, 2PHZ, 2MA-OK, 2PZ-OK (available from Shikoku Chemicals Corporation under these trade names), and compounds obtained after adding these imidazoles to an epoxy resin. The curing agent may be used in the form of a microcapsule by being coated with a polymer material such as a polyurethane or polyester polymer material. The curing agent is used in an appropriately adjusted amount. Preferably, the amount is adjusted so that the stoichiometric equivalent ratio of the curing agent with respect to the epoxy equivalent of the epoxy resin ranges from 0.8 to 1.2. With the curing agent content falling in this range, the connection reliability and the high-temperature repairability of the components at the joint can effectively improve.

### Curing Promoting Agent

Aside from imidazoles such as above, the curing promoting agent may be selected from: cyclic amines such as tertiary amines, 1,8-diazabicyclo(5.4.0)undecene-7, and 1,5-diazabicyclo(4.3.0)nonene-5, and tetraphenylborate salts thereof; trialkylphosphines such as tributylphosphine; triarylphosphines such as triphenylphosphine; quaternary phosphonium salts such as tetraphenyl phosphonium tetraphenyl borate, and tetra(n-butyl)phosphonium tetraphenyl borate; metal complexes such as Fe acetyl acetonate, and adduct compounds thereof. The content of the curing promoting agent is appropriately adjusted, taking into consideration factors such as gelation time, and storage stability. With the content of the curing promoting agent falling in an appropriately adjusted range in the flux of the embodiment of the present disclosure, the connection reliability and the high-temperature repairability of the components at the joint can effectively improve.

### Organic Acid

The organic acid (activating agent) is not particularly limited, and acids of any organic compounds may be used. Examples of the organic acid include rosin component materials such as abietic acid; various amines and salts thereof; sebacic acid, adipic acid, glutaric acid, succinic acid, malonic acid, citric acid, and pimelic acid. The organic acid has a desirable fluxing effect (as used herein, “fluxing effect” means the reducing effect that removes the oxide coating that has occurred on the metal surface to which the solder paste is applied, and the effect that lowers the surface tension of a molten solder to promote solder wettability for the soldered metal surface). These organic acids may be used as a single component, or as a mixture of two or more components. Preferred among these organic acids are adipic acid and glutaric acid because these have a high fluxing effect, and are stable as compounds. The organic acid is used in an appropriately adjusted amount, and is used preferably in a stoicheiometric equivalent ratio of 0.8 to 1.2 with respect to an epoxy equivalent of the epoxy resin. With the organic acid content falling in this range, the connection reliability and the high-temperature repairability of the components at the joint can effectively improve.

The following describes an exemplary method for adjusting the solder paste of the embodiment of the present disclosure, and an exemplary method for producing a mount structure.

First, the flux is produced by weighing and mixing an epoxy resin, a curing agent, a rubber modified epoxy resin, an organic acid, and, optionally, a curing promoting agent. The solder powder is then added to the flux, and mixed and kneaded to obtain the solder powder of the embodiment of the present disclosure.

A mount structure of the embodiment of the present disclosure can be obtained by mounting a semiconductor component, on, for example, a circuit board having conductive wires, using the solder paste of the embodiment of the present disclosure. The solder paste can be applied to the circuit board as follows, for example. A metal mask having a plurality of through holes corresponding in position to the electrodes on the circuit board is laid over the circuit board. The solder paste is then applied to the surface of the metal mask, and the through holes are filled with the solder paste using a squeegee. Removing the metal mask from the circuit board results in the solder paste being applied to each electrode on the circuit board.

While the solder paste is in an uncured state, a chip component or a semiconductor component is stacked on the circuit board with the terminal of the chip component or the semiconductor component and the electrode of the circuit board facing each other, using a tool such as a chip mounter. Here, the chip component may be, for example, a chip resistor or a chip capacitor. The semiconductor component may be, for example, a CSP or BGA semiconductor package having a solder ball as the terminal, or a QFP semiconductor package provided with a lead terminal. The semiconductor component also may be a semiconductor device (bare chip) provided with a terminal without being housed in a package.

In this state, the printed wiring board with the chip component is heated to a predetermined heating temperature with a reflow furnace. The heating temperature is appropriately set to a temperature that sufficiently melts the solder powder, and at which the cure reaction of the resin component sufficiently proceeds. Preferably, the heating temperature is set so that the agglomeration and melting of the solder powder will not be inhibited by the progression of the cure reaction of the epoxy resin before the solder powder completely melts. The preferred heating temperature to this end is a temperature that is equal to or greater than the melting point of the solder powder, and that is equal to or greater than the cure temperature of the flux containing the resin. Specifically, the preferred heating temperature is a temperature that is at least 10° C. higher than the melting point of the solder powder, and that is at most 60° C. higher than the melting point of the solder powder.

After these processes, a semiconductor device of the embodiment of the present disclosure is produced that has a joint where the terminal of the semiconductor component and the electrode of the circuit board are connected to each other via the solder paste of the embodiment of the present disclosure. The joint includes the solder powder, a conductive portion where the solder ball has melted and integrated, and a reinforcing portion, which is a cured epoxy resin portion covering the periphery of the conductive portion. In this manner, the solder paste of the embodiment of the present disclosure can be used to produce a mount structure in which a component and a substrate are electrically bonded to each other with the conductive portion, and the reinforcing portion provides mechanical reinforcement.

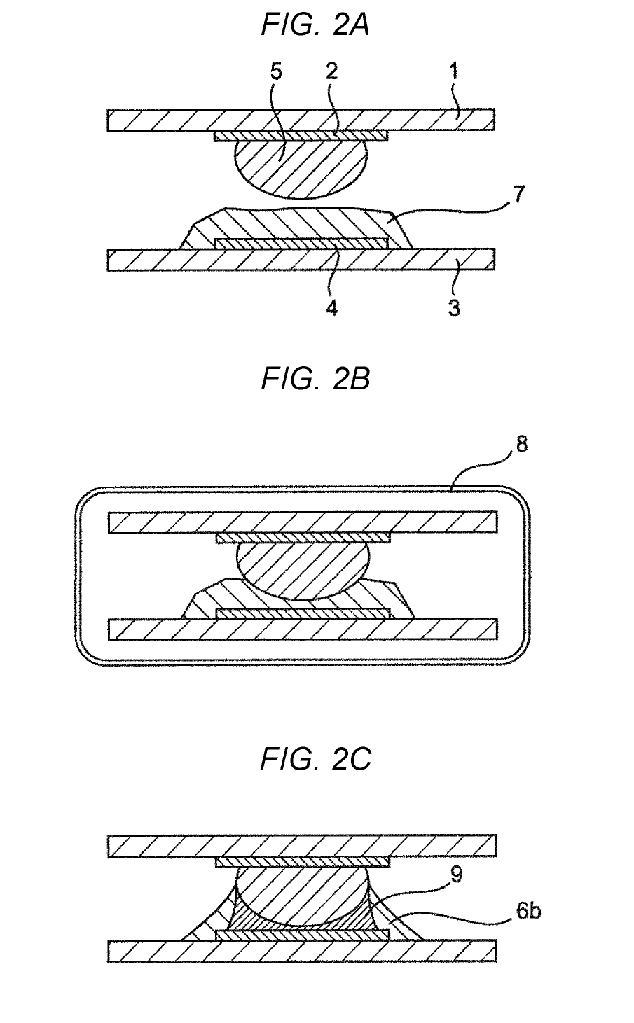

FIGS. 2A to 2C are cross sectional explanatory diagrams schematically representing a process for connecting a ball portion of a CSP in an embodiment of the present disclosure. As illustrated in FIG. 2A, an electrode 2 provided on a circuit board 1, and an electrode 4 provided on a circuit board 3 are bonded to each other with a solder bump 5 and a solder paste 7. Amount structure having a reinforcing portion 6b and a conductive portion 9 as shown in FIG. 2C is produced upon heat curing with a drier 8 as shown in FIG. 2B.

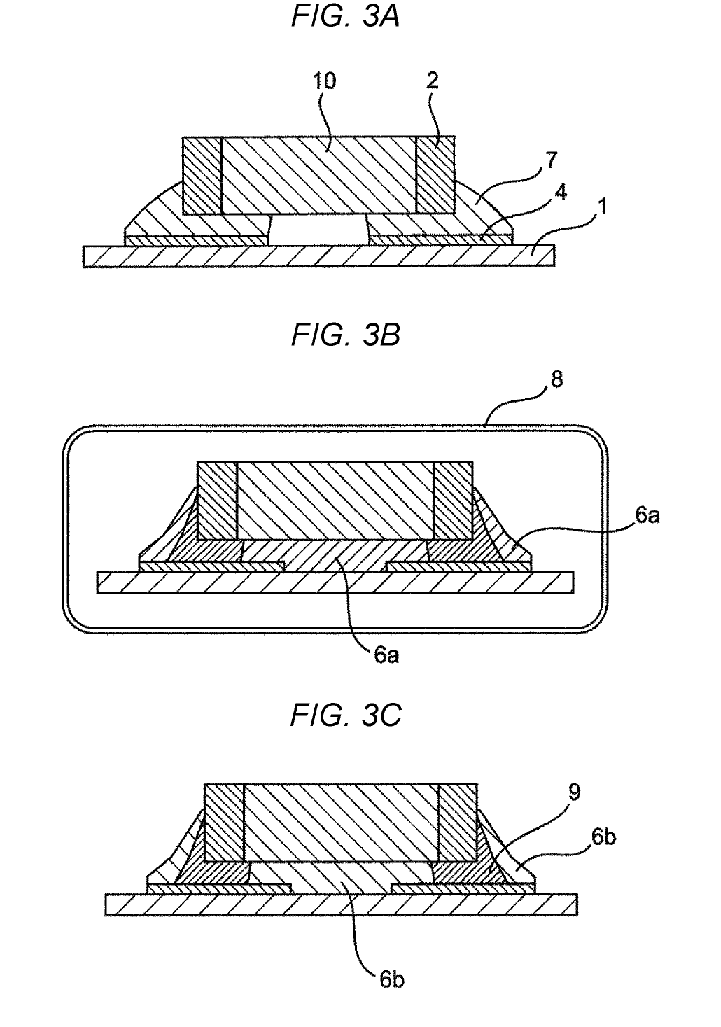

FIGS. 3A to 3C are cross sectional explanatory diagrams schematically representing a process for bonding a chip component with the solder paste of the embodiment of the present disclosure. As illustrated in FIG. 3A, a chip component 10 is mounted on the solder paste 7 applied onto an electrode 4 provided on a circuit board 1, and the solder paste 7 is heat cured with a drier 8. This causes the solder powder contained in the solder paste to melt and/or agglomerate, and the surface tension and/or the cohesive force of the solder powder push the epoxy resin 6a, which then covers the periphery of the solder, and the bottom of the chip. This forms the structure shown in FIG. 3B. The epoxy resin 6a cures upon being heat cured with the drier 8, and a mount structure having a reinforcing portion 6b and a conductive portion 9 is produced, as shown in FIG. 3C.

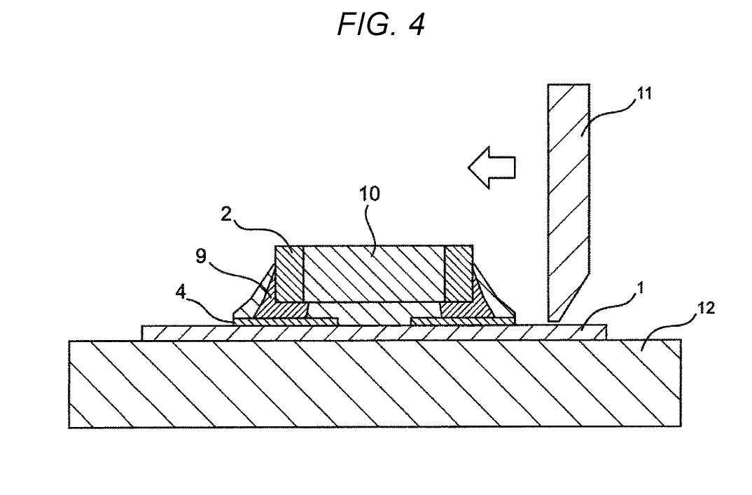

FIG. 4 is a schematic view representing a method for measuring the shear strength of a chip component bonded by using the solder paste of the embodiment of the present disclosure in the manner shown in FIGS. 3A to 3C. The chip component is fixed on a heatable hot plate stage 12, and horizontally pushed with a shear jig 11 to measure adhesion strength.

The following describes Examples and Comparative Examples of the present disclosure. It is to be noted that the forms of the Examples and Comparative Examples of the present disclosure below are merely illustrative, and are not intended to limit the present disclosure in any way.

### Examples

### Production of Solder Paste

First, an epoxy resin, a rubber modified epoxy resin, an organic acid, and a curing agent were weighed so that these components were contained in the solder paste in the weight parts shown in Table 1. These components were placed and kneaded in a planetary mixer, and uniformly dispersed in the epoxy resin to produce the fluxes of Examples 1 to 7 and Comparative Examples 1 to 4. The bisphenol-F epoxy resin jER806 available from Japan Epoxy Resin Co., Ltd. was used as the epoxy resin. The polybutadiene-modified epoxy resin R-15EPT available from Nagase ChemteX Corporation, and the urethane-modified epoxy resin EPU-7N available from ADEKA were appropriately used as the rubber modified epoxy resin. A glutaric acid product from Kanto Kagaku was used as the organic acid. The imidazole-based curing agent 2P4MHZ (2-phenyl-4-methyl-5-hydroxymethylimidazole) available from Shikoku Chemicals Corporation was used as the curing agent.

A solder powder was added to the fluxes of Examples 1 to 10 and Comparative Examples 1 to 4 in the weight parts shown in Table 1, and the mixture was kneaded to prepare a solder paste. The solder powder used in Examples 1 to 6 and Examples 8 to 10 had the solder composition 42Sn-58Bi specified by JIS H42B:58A. The solder powder used in Example 7 had the composition 425n-57Bi-1.0Ag. The solder powder was produced according to an ordinary method. The solder particles had an average particle size of 15 μm, and a melting point of 139° C.

As used herein, “average particle size” is the particle size (D50) at a cumulative 50% point on a cumulative curve with respect to a total 100% volume in a volume-based particle size distribution. Average particle size can be measured using a laser-diffraction scattering particle-size and particle-distribution measurement device, or a scanning electron microscope.

### Production of Adhesion Evaluation Sample

The solder paste produced in the manner described above was printed on an Au-plated electrode on a circuit board (FR-4 substrate) in a thickness of 0.1 mm to form a solder paste printed portion, using a metal mask.

A chip resistor (tin electrode) measuring 3.2 mm×1.6 mm in size was then mounted on the solder paste printed portion on the circuit board, using a chip mounter. The circuit board used copper as electrode material, and a glass epoxy material as substrate material. Using a reflow device, the whole setup was heated at 160° C. for 6 minutes to form a joint, and produce an evaluation sample.

### Evaluation

The printability of the solder paste was evaluated by observing the shape of the solder pasted printed with a metal mask. In the observation, the solder paste was visually checked for the extent of confinement in the electrode area, dripping, and pointing. The evaluation results for Examples 1 to 10 and Comparative Examples 1 to 4 are presented in Table 1, along with the characteristics of the solder pastes used in Examples and Comparative Examples. In the table, the evaluation of printability is based on the transferred shape of the paste on the electrode of the circuit board through the through holes of the mask. The printability was Good when the shape was maintained in the electrode portion and the chip was mountable, Poor when a bridge occurred between the electrodes or when the electrode was exposed, and Acceptable when the chip was mountable but the shape was partially disrupted (dripping, pointing).

The room-temperature adhesion of the solder paste was evaluated by measuring the shear adhesion of the adhesion evaluation sample at room temperature (20° C.) using a DAGE Series 4000 bond tester as schematically illustrated in FIG. 4. The evaluation results for Examples 1 to 10 and Comparative Examples 1 to 4 are presented in Table 1, along with the characteristics of the solder pastes used in Examples and Comparative Examples. In the table, the evaluation result is Good when the joint remained undamaged even under an applied load of more than 20 kgf (196 N), Acceptable when the joint was damaged under an applied load of 20 kgf or less and 14 kgf or more (196 N or less and 137.2 N or more), and Poor when the joint was damaged under an applied load of less than 14 kgf (137.2 N).

The solder paste was also evaluated for high-temperature adhesion by measuring the shear adhesion in the same manner as above, except that the measurement was made after the evaluation sample was heated to 160° C. by heating the hot plate with the evaluation sample fixed on the hot plate stage 12 as shown in FIG. 4. The evaluation results for Examples 1 to 7 and Comparative Examples 1 to 4 are presented in Table 1, along with the characteristics of the solder pastes used in Examples and Comparative Examples. In the table, the evaluation result is Good when the joint was removable under an applied load of 3 kgf (29.4 N) or less, Acceptable when the joint was removable under an applied load of 4 kgf or more and 7 kgf or less (19.6 N or less and 68.6 N or more), and Poor when an applied load of 8 kgf (78.4 N) or more was needed to remove the joint.

The overall evaluation result was Excellent when the result was Good for all three evaluations, Good when the result was Good for two of the evaluations, Acceptable when the result was Good for only one of the evaluations, and Poor when the result was Poor in any of the evaluations.

TABLE 1

| | | | | Ex. 1 | Ex. 2 | Ex. 3 | Ex. 4 | Ex. 5 |
|---|---|---|---|---|---|---|---|---|
| Formulation | Solder | | Type | SB | SB | SB | SB | SB |
| | | | Weight parts | 80 | 82 | 84 | 78 | 80 |
| | Flux | Base epoxy | Weight parts | 8.7 | 9.0 | 8.8 | 8.9 | 10.0 |
| | | Polybutadiene | Weight parts | 6.0 | 2.7 | 1.1 | 4.4 | 0.0 |
| | | modified | phr | 30 | 15 | 7 | 20 | 0 |
| | | epoxy resin | | | | | | |
| | | Urethane | Weight parts | 0.0 | 0.9 | 0.8 | 3.3 | 4.0 |
| | | modified | phr | 0 | 5 | 5 | 15 | 20 |
| | | epoxy resin | | | | | | |
| | | Activating | Weight parts | 3.5 | 3.6 | 3.5 | 3.6 | 4.0 |
| | | agent | | | | | | |
| | | Curing agent | Weight parts | 1.8 | 1.8 | 1.8 | 1.8 | 2.0 |
| | Total flux (weight parts) | | | 20.0 | 18.0 | 16.0 | 22.0 | 20.0 |
| | Total of rubber modified epoxy resin | | | 6.0 | 3.6 | 1.9 | 7.7 | 4.0 |
| | (weight parts) | | | | | | | |
| | Total paste (weight parts) | | | 100 | 100 | 100 | 100 | 100 |
| Proportion | Proportion of flux (%) | | | 20 | 18 | 16 | 22 | 20 |
| | Proportion of solder (%) | | | 80 | 82 | 84 | 78 | 80 |
| Characteristics | Printability | | | Acceptable | Good | Good | Acceptable | Acceptable |
| | Adhesion | Room | Kg/chip | 14 | 17 | 20 | 21 | 22 |
| | | temperature | Evaluation | Acceptable | Acceptable | Good | Good | Good |
| | | 160° C. | Kg/chip | 0.5 | 2 | 3 | 1.5 | 6 |
| | | | Evaluation | Good | Good | Good | Good | Acceptable |
| Overall evaluation | | | | Acceptable | Good | Excellent | Good | Acceptable |
| | | | | Ex. 6 | Ex. 7 | Ex. 8 | Ex. 9 | Ex. 10 |
| Formulation | Solder | | Type | SB | SBA | SB | SB | SB |
| | | | Weight parts | 85 | 84 | 78 | 80 | 84 |
| | Flux | Base epoxy | Weight parts | 9.1 | 8.8 | 15.9 | 12.7 | 8.3 |
| | | Polybutadiene | Weight parts | 0.30 | 1.1 | 0.0 | 0.0 | 0.0 |
| | | modified | phr | 2 | 7 | 0 | 0 | 0 |
| | | epoxy resin | | | | | | |
| | | Urethane | Weight parts | 0.15 | 0.8 | 0.7 | 2.0 | 2.4 |
| | | modified | phr | 1 | 5 | 3 | 10 | 15 |
| | | epoxy resin | | | | | | |
| | | Activating | Weight parts | 3.65 | 3.5 | 3.6 | 3.5 | 3.5 |
| | | agent | | | | | | |
| | | Curing agent | Weight parts | 1.8 | 1.8 | 1.8 | 1.8 | 1.8 |
| | Total flux (weight parts) | | | 15.0 | 16.0 | 22.0 | 20.0 | 16.0 |
| | Total of rubber modified epoxy resin | | | 0.45 | 1.9 | 0.2 | 2.0 | 2.4 |
| | (weight parts) | | | | | | | |
| | Total paste (weight parts) | | | 100 | 100 | 100 | 100 | 100 |
| Proportion | Proportion of flux (%) | | | 15 | 16 | 22 | 20 | 16 |
| | Proportion of solder (%) | | | 85 | 84 | 78 | 80 | 84 |
| Characteristics | Printability | | | Good | Good | Good | Good | Acceptable |
| | Adhesion | Room | Kg/chip | 15 | 22 | 16 | 19 | 24 |
| | | temperature | Evaluation | Acceptable | Good | Acceptable | Acceptable | Good |
| | | 160° C. | Kg/chip | 5 | 3 | 7 | 6 | 6 |
| | | | Evaluation | Acceptable | Good | Acceptable | Acceptable | Acceptable |

| | | | | | |
|---|---|---|---|---|---|
| Overall evaluation | Acceptable | Excellent | Acceptable | Acceptable | Acceptable |

| | | | | Com. Ex. 1 | Com. Ex. 2 | Com. Ex. 3 | Com. Ex. 4 |
|---|---|---|---|---|---|---|---|
| Formulation | Solder | | Type | SB | SB | SB | SB |
| | | | Weight parts | 84 | 78 | 80 | 78 |
| | Flux | Base epoxy | Weight parts | 10.0 | 6.9 | 7.5 | 6.9 |
| | | Polybutadiene | Weight parts | 0.0 | 11.0 | 0.0 | 6.6 |
| | | modified | phr | 0 | 50 | 0 | 30 |
| | | epoxy resin | | | | | |
| | | Urethane | Weight parts | 0.0 | 0.0 | 8.0 | 4.4 |
| | | modified | phr | 0 | 0 | 40 | 20 |
| | | epoxy resin | | | | | |
| | | Activating | Weight parts | 4.0 | 2.7 | 3.0 | 2.7 |
| | | agent | | | | | |
| | | Curing agent | Weight parts | 2.0 | 1.4 | 1.5 | 1.4 |
| | Total flux (weight parts) | | | 16.0 | 22.0 | 20.0 | 22.0 |
| | Total of rubber modified epoxy resin | | | 0.0 | 11.0 | 8.0 | 11.0 |
| | (weight parts) | | | | | | |
| | Total paste (weight parts) | | | 100 | 100 | 100 | 100 |
| Proportion | Proportion of flux (%) | | | 16 | 22 | 20 | 22 |
| | Proportion of solder (%) | | | 84 | 78 | 80 | 78 |
| Characteristics | Printability | | | Good | Poor | Poor | Poor |
| | Adhesion | Room | Kg/chip | 10 | 5 | 16 | 18 |
| | | temperature | Evaluation | Poor | Poor | Acceptable | Acceptable |
| | | 160° C. | Kg/chip | 7 | 0.5 | 4 | 0.5 |
| | | | Evaluation | Acceptable | Good | Acceptable | Good |

| | | | | |
|---|---|---|---|---|
| Overall evaluation | Poor | Poor | Poor | Poor |

The solder powder used in Example 1 was of the composition 42Sn-58Bi (“SB” in the table), and was used in 80 weight parts with respect to 100 weight parts of the solder paste. The polybutadiene modified epoxy resin was used in 30 weight parts (30 phr) for 100 weight parts of the flux (a total weight of solder paste components other than the solder powder). The solder paste did not contain the urethane-modified epoxy resin. The solder paste contained the activating agent and the curing agent in proportions of 40 weight % and 20 weight %, respectively, with respect to the weight, 100, of the epoxy resin (excluding the rubber modified epoxy resin).

In Example 1, the solder paste was slightly pointed, and the printability was Acceptable. In Example 1, the joint adhesion was 14 kgf at room temperature, but was much lower (0.5 kgf) at 160° C. It can be said from this result that the high-temperature repairability is excellent in Example 1.

In Example 2, the solder powder was of the composition 42Sn-58Bi as in Example 1, and the proportion of the solder was 82 weight % for 100 weight parts of the solder paste. The proportion of the polybutadiene modified epoxy resin was 15 phr, and the proportion of the urethane-modified epoxy resin was 5 phr. The activating agent and the curing agent were used in 40 weight % and 20 weight %, respectively, with respect to the weight of the epoxy resin, as in Example 1.

The paste of Example 2 had desirable printability, and the evaluation result was Good. The adhesion at room temperature was higher than in Comparative Example 1 in which the solder paste did not contain the rubber modified epoxy. However, as a result of the adhesion at 160° C. was lower than the adhesion at room temperature, it can be said that the repairability is desirable.

In Examples 3 to 6 and Examples 8 to 10, solder pastes were prepared in the same manner as in Example 1, except that the proportions of the solder powder and other components for 100 weight parts of the solder paste were varied as shown in Table 1. The results of printability and adhesion evaluations are as shown in Table 1.

In Example 7, a solder paste was prepared under the same conditions used in Example 3, except that the solder powder had the composition 42Sn-57Bi-1.0Ag (“SBA” in the table). The results of printability and adhesion evaluations are as shown in Table 1.

In Comparative Example 1, a solder paste was prepared without using the rubber modified epoxy resin. The proportions of the solder powder and other components for 100 weight parts of the solder paste are as shown in Table 1. There was no problem in the printability of the solder paste in Comparative Example 1. However, the overall evaluation was Poor because of the poor room-temperature adhesion involving damage under a load below 15 kgf (147 N).

In Comparative Example 2, a solder paste was prepared by using the polybutadiene modified epoxy resin in a proportion of 50 phr, and by making the solder proportion 78 weight %, without using the urethane-modified epoxy resin. The solder paste of Comparative Example 2 was pointed, and was damaged under an applied load of 5 kgf, below 15 kgf. The evaluation result was therefore Poor for printability and room-temperature adhesion, and the overall evaluation was Poor.

In Comparative Example 3, a solder paste was prepared by using the urethane modified epoxy resin in a proportion of 40 phr, and by making the solder proportion 80 weight %, without using the polybutadiene-modified epoxy resin. The solder paste of Comparative Example 3 was pointed, and the printability was Poor. The overall evaluation was Poor accordingly.

In Comparative Example 4, the polybutadiene modified epoxy resin and the urethane-modified epoxy resin were used in 30 weight % and 20 weight %, respectively, with respect to the total flux weight. The proportions of the solder powder and other components for 100 weight parts of the solder paste are as shown in Table 1. The solder paste of Comparative Example 4 was pointed, and the printability was Poor. The overall evaluation was Poor accordingly.

It was found from the results shown in Table 1 that, when 3 weight % to 35 weight % of rubber modified epoxy resin with respect to the total flux weight is added, a solder paste containing an epoxy resin, a curing agent, an organic acid, and a solder powder can form a joint that is easily removable at high temperature while maintaining high adhesion at room temperature where a semiconductor component operates.

Specifically, when the rubber modified epoxy resin is an epoxy resin containing a butadiene skeleton, and is contained in a proportion of 2 weight % to 30 weight % with respect to the total flux, the adhesion strength of a chip component was found to decrease in a high-temperature range equal to or greater than the Tg of the resin flux, as compared to when the solder paste does not contain the rubber modified epoxy resin. When the rubber modified epoxy resin is an epoxy resin containing a urethane skeleton, and is contained in a proportion of 1 weight % to 20 weight % with respect to the total flux, the room-temperature adhesion strength of a chip component was found to increase as compared to when the solder paste does not contain the rubber modified epoxy resin.

The adhesion also improved when the epoxy resin containing a butadiene skeleton, and an epoxy resin containing a urethane skeleton were both contained as the rubber modified epoxy resin. Specifically, in a high-temperature range equal to or greater than the Tg of the resin flux, the solder paste containing 2 weight % to 20 weight % of a butadiene skeleton-containing epoxy resin, and 1 weight % to 15 weight % of a urethane skeleton-containing epoxy resin with respect to the total flux was found to have lower adhesion than a solder paste that does not contain the rubber modified epoxy resin. At room temperature, the solder paste containing 2 weight % to 20 weight % of a butadiene skeleton-containing epoxy resin, and 1 weight % to 15 weight % of a urethane skeleton-containing epoxy resin with respect to the total flux was found to have higher adhesion than a solder paste does not contain the rubber modified epoxy resin. As demonstrated above, it was indeed possible to satisfy both high adhesion at room temperature, and low adhesion at high temperature.

The solder paste and the mount structure of the embodiment of the present disclosure are applicable to a wide range of applications in the field of techniques for forming electric/electronic circuits. For example, the disclosure is applicable for connecting electronic components such as CCD devices, hologram devices, and chip components, and for bonding such components to a substrate. The disclosure is therefore applicable to products in which such devices, components, and substrates are installed, for example, such as DVD devices, cell phones, portable AV devices, and digital cameras.

What is claimed is:

1. A solder paste comprising a solder powder and a flux,
the flux containing an epoxy resin, a curing agent, a rubber modified epoxy resin, and an organic acid,
the rubber modified epoxy resin being contained in a proportion of 3 weight % to 35 weight % with respect to a total weight of the flux.

2. The solder paste according to claim 1, wherein the rubber modified epoxy resin contains an epoxy resin having a urethane skeleton, the epoxy resin having a urethane skeleton being contained in a proportion of 1 weight % to 20 weight % with respect to the total weight of the flux.

3. The solder paste according to claim 1, wherein the rubber modified epoxy resin contains an epoxy resin having a butadiene skeleton, the epoxy resin having a butadiene skeleton being contained in a proportion of 2 weight % to 30 weight % with respect to the total weight of the flux.

4. The solder paste according to claim 1, wherein the rubber modified epoxy resin contains an epoxy resin having a butadiene skeleton, and an epoxy resin having a urethane skeleton, the epoxy resin having a butadiene skeleton being contained in a proportion of 2 weight % to 20 weight % with respect to the total weight of the flux, the epoxy resin having a urethane skeleton being contained in a proportion of 1 weight % to 15 weight % with respect to the total weight of the flux.

5. The solder paste according to claim 1, wherein the solder powder contains 22 weight % to 68 weight % of Bi, 0 weight % to 2 weight % of Ag, 0 weight % to 73 weight % of In, and the balance tin.

6. A mount structure comprising a component mounted on a circuit board with the solder paste of claim 2,
wherein the adhesion strength between the component and the circuit board in a high-temperature range equal to or greater than the glass transition point of the flux is weaker than when a solder paste that does not contain the rubber modified epoxy resin is used.

7. A mount structure comprising a component mounted on a circuit board with the solder paste of claim 3,
wherein the adhesion strength between the component and the circuit board at room temperature is stronger than when a solder paste that does not contain the rubber modified epoxy resin is used.

8. A mount structure comprising a component mounted on a circuit board with the solder paste of claim 1,
wherein mount structure has a conductive portion where the component and the circuit board are metallically bonded to each other, and a reinforcing portion formed by a cured product of the flux covering the periphery of the conductive portion.

9. The solder paste according to claim 1, wherein the flux further comprises a thixotropy imparting agent and a low-boiling-point solvent.

10. The solder paste according to claim 1, wherein the flux is 5 weigh % to 60 weight % with respect to the total weight of the solder paste.

11. The solder paste of claim 10, wherein the flux is 15 weight % to 22 weight % with respect to the total weight of the solder paste.

12. The solder paste according to claim 2, wherein the solder powder contains 22 weight % to 68 weight % of Bi, 0 weight % to 2 weight % of Ag, 0 weight % to 73 weight % of In, and the balance tin.

13. The solder paste according to claim 3, wherein the solder powder contains 22 weight % to 68 weight % of Bi, 0 weight % to 2 weight % of Ag, 0 weight % to 73 weight % of In, and the balance tin.

14. The solder paste according to claim 4, wherein the solder powder contains 22 weight % to 68 weight % of Bi, 0 weight % to 2 weight % of Ag, 0 weight % to 73 weight % of In, and the balance tin.

15. A mount structure comprising a component mounted on a circuit board with the solder paste of claim 4,
wherein the adhesion strength between the component and the circuit board in a high-temperature range equal to or greater than the glass transition point of the flux is weaker than when a solder paste that does not contain the rubber modified epoxy resin is used.

16. A mount structure comprising a component mounted on a circuit board with the solder paste of claim 4,
wherein the adhesion strength between the component and the circuit board at room temperature is stronger than when a solder paste that does not contain the rubber modified epoxy resin is used.
